(19) United States
(12) Patent Application Publication
(10) Pub. No.: US 2024/0186273 A1
(43) Pub. Date: Jun. 6, 2024

(54) SEMICONDUCTOR DEVICE

(71) Applicant: Kioxia Corporation, Tokyo (JP)

(72) Inventors: Hitoshi IKEI, Yokohama (JP); Takashi MATSUO, Yokohama (JP); Tsunehiro KITA, Fujisawa (JP)

(73) Assignee: Kioxia Corporation, Tokyo (JP)

(21) Appl. No.: 18/444,066

(22) Filed: Feb. 16, 2024

Related U.S. Application Data
(63) Continuation of application No. PCT/JP2022/013702, filed on Mar. 23, 2022.

(30) Foreign Application Priority Data
Sep. 2, 2021 (JP) 2021-143433

(51) Int. Cl. H01L 23/00

(52) U.S. Cl. CPC H01L 24/08; H01L 24/05; H01L 2224/05124; H01L 2224/05624; H01L 2224/08225

(57) ABSTRACT

A semiconductor device includes a semiconductor chip including a wiring layer formed on a first side, a first pad formed so as to protrude from a surface of a passivation film on the first side, and an interlayer film formed between the first side and the wiring layer on one side and the passivation film and the first pad on another side, and a mounting substrate including a second pad on the second side, and the first pad and the second pad are in contact with each other. A thickness of the interlayer film between the wiring layer and the first pad is 0.5 to 2.8 μm. The first pad is disposed between formation regions of internal circuits provided on the semiconductor chip.

### CROSS-REFERENCE TO RELATED APPLICATIONS

This application is a continuation application of PCT/JP2022/013702 filed on Mar. 23, 2022 and claims the benefit of priority from the prior Japanese Patent Application No. 2021-143433 filed in Japan on Sep. 2, 2021, the entire contents of which are incorporated herein by reference.

### TECHNICAL FIELD

Embodiments of the present invention relate to a semiconductor device.

### BACKGROUND ART

There is a technique of bumplessly installing a semiconductor chip onto a substrate. A plurality of pads of the semiconductor chip need to be respectively reliably connected to a plurality of contact pads on the substrate.

### BRIEF DESCRIPTION OF THE DRAWINGS

FIG. 1 is a perspective view of a semiconductor chip and a substrate onto which the semiconductor chip is mounted of a first embodiment;

FIG. 2 is a sectional view of the semiconductor chip and the substrate of the first embodiment in a state where the semiconductor chip is installed on the mounting substrate;

FIG. 3 is a sectional view of one pad of the semiconductor chip of the first embodiment;

FIG. 4 is a sectional view of one pad of the semiconductor chip of the first embodiment that has a different configuration from FIG. 3;

FIG. 5 is a view for describing a manufacturing method of the pads of the semiconductor chip of the first embodiment;

FIG. 6 is a view for describing the manufacturing method of the pads of the semiconductor chip of the first embodiment;

FIG. 7 is a view for describing a method of bumplessly installing the semiconductor chip onto the mounting substrate of the first embodiment;

FIG. 8 is a view for describing a surface activation process for the semiconductor chip and the mounting substrate of the first embodiment;

FIG. 9 is a view for describing bonding of the semiconductor chip and the mounting substrate of the first embodiment;

FIG. 10 is a view for describing joining of the pads of the semiconductor chip and pads of the mounting substrate of the first embodiment;

FIG. 11 is a view for describing joining of the pads of the semiconductor chip and the pads of the mounting substrate of the first embodiment;

FIG. 12 is a view for describing unifying the pads of the semiconductor chip and the pads of the mounting substrate by joining these pads together;

FIG. 13 is a sectional view of a chip pad 31 according to a second embodiment;

FIG. 14 is an explanatory diagram for describing a state where the chip pads 31 are disposed on a layer above a wiring layer 32;

FIG. 15 is an explanatory diagram for describing a state where the chip pads 31 are disposed on the layer above the wiring layer 32;

FIG. 16 is an explanatory diagram for describing a state where the chip pads 31 are disposed on the layer above the wiring layer 32;

FIG. 17 is a sectional view showing a third embodiment;

FIG. 18 is a view for describing a manufacturing method of contact pads 51; and

FIG. 19 is a view for describing the manufacturing method of the contact pads 51.

### BEST MODE FOR CARRYING OUT THE INVENTION

A semiconductor device of an embodiment includes a semiconductor chip including a passivation film on a first side, and a mounting substrate including a second side facing the first side of the semiconductor chip. The semiconductor chip includes a wiring layer formed on the first side, a first pad formed on the first side so as to protrude from a surface of the passivation film, and an interlayer film formed between the first side and the wiring layer on one side and the passivation film and the first pad on another side. The mounting substrate includes a second pad on the second side. The first pad and the second pad are in contact with each other in a state where an oxide film or an adsorbate is removed from a contact region between the first pad and the second pad. A thickness of the interlayer film between the wiring layer and the first pad is 0.5 to 2.8 μm. The semiconductor chip includes a plurality of internal circuits provided adjacent to one another. The first pad is disposed between formation regions of the internal circuits.

Embodiments will be described below with reference to the drawings.

In each drawing used for the following description, the scale is varied among constituent elements to make each constituent element large enough to recognize in the drawing, and the present invention is not limited to the quantities of the constituent elements, the shapes of the constituent elements, the ratios in size among the constituent elements, and the relative positional relationships among the constituent elements that are depicted in the drawings.

### First Embodiment

### (Configuration)

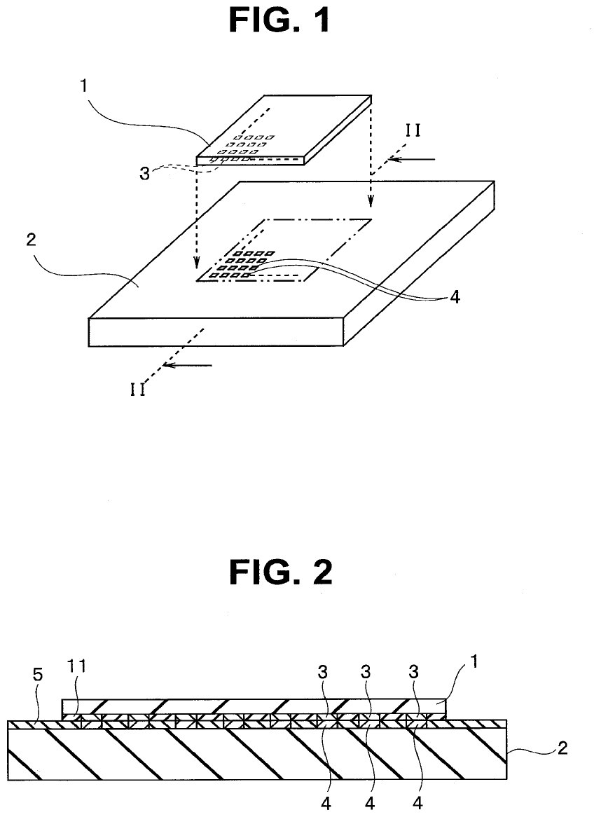

FIG. 1 is a perspective view of a semiconductor chip 1 and a substrate 2 onto which the semiconductor chip 1 is mounted of a first embodiment. The semiconductor chip 1 is a bare chip that has been cut out and singulated from a semiconductor wafer. In FIG. 1, the semiconductor chip 1 is mounted onto the substrate 2 by a flip-chip method.

To simplify the description, an example in which one semiconductor chip (hereinafter also referred to as a chip) 1 is installed onto the substrate 2 that is a mounting substrate will be described here, but a plurality of semiconductor chips 1 may be installed onto the substrate 2. Further, when a plurality of semiconductor chips 1 are installed onto the substrate 2, the plurality of semiconductor chips 1 may be different types of devices from one another.

The semiconductor chip 1 is a plate-shaped chip and has a plurality of pads (hereinafter referred to as chip pads) 3 for electrical connection to the substrate 2. The plurality of chip pads 3 are provided on one side of the semiconductor chip 1 (in FIG. 1, a lower surface of the semiconductor chip 1).

On the other hand, the substrate 2 also has a plurality of pads (hereinafter referred to as contact pads) 4 for electrical connection to the semiconductor chip 1 on a side onto which the semiconductor chip 1 is mounted. The plurality of contact pads 4 are provided on one side of the substrate 2 (in FIG. 1, an upper surface of the substrate 2). As will be described later, the semiconductor chip 1 is bonded with the substrate 2 in a high-vacuum environment.

FIG. 2 is a sectional view of the semiconductor chip 1 and the substrate 2 in a state where the semiconductor chip 1 is installed on the substrate 2. FIG. 2 shows sections of the semiconductor chip 1 and the substrate 2 along line II-II of FIG. 1.

The plurality of chip pads 3 of the semiconductor chip 1 are respectively brought into contact with and electrically connected to the contact pads 4 of the substrate 2 by flip-chip mounting.

Flip-chip mounting is widely used in place of wire-bonding mounting to respond to demands for downsizing and thinning of semiconductor memory packages. In particular, flip-chip mounting has been increasingly adopted as mobile information terminals and the like have gained higher performance and higher functions. Flip-chip mounting is also adopted for MCPs (multi-chip-packages) in which a plurality of chips are stacked.

The substrate 2 on which the semiconductor chip 1 is mounted as shown in FIG. 2 is installed inside various devices. For example, the semiconductor chip 1 is a chip of a NAND flash memory that is a non-volatile memory, or a chip of a memory controller that controls a non-volatile memory. The substrate 2 on which one or more than one chip 1 is mounted is installed inside an SSD (solid state drive) device.

The semiconductor chip 1 has a passivation film 11 on one side. The plurality of chip pads 3 of the semiconductor chip 1 are respectively provided in a plurality of openings that are provided in the passivation film 11 of the semiconductor chip 1. Each chip pad 3 is electrically connected to wiring inside the semiconductor chip 1.

On the other hand, the plurality of contact pads 4 on the substrate 2 are provided on a surface onto which the semiconductor chip 1 is mounted. Thus, the substrate 2 has the plurality of contact pads 4 on the side facing the side of the semiconductor chip 1 having the plurality of chip pads 3. A solder resist 5 is applied to that surface. The solder resist 5 is not applied to a surface of each of the plurality of contact pads 4.

### (Configuration of Chip Pads)

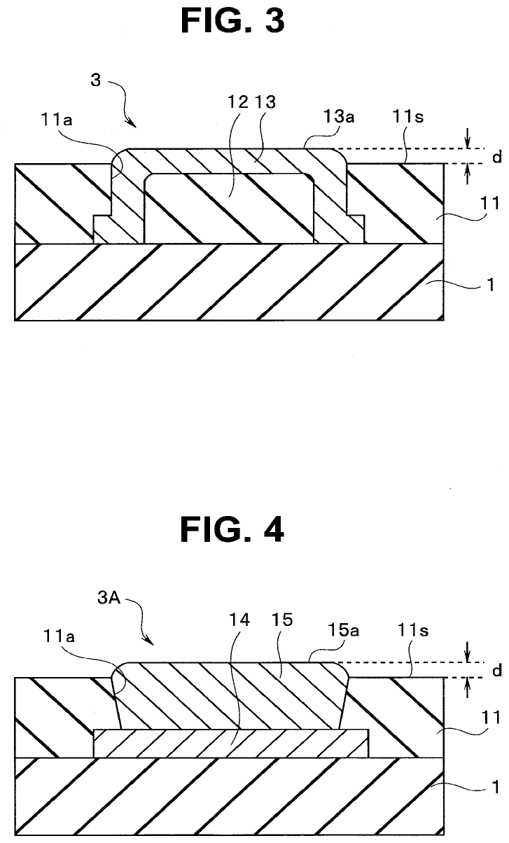

Each of the plurality of chip pads 3 is provided so as to protrude from a surface of the passivation film 11. FIG. 3 is a sectional view of one chip pad 3.

The chip pads 3 are formed so as to protrude through openings 11a of the passivation film 11 of the semiconductor chip 1. More specifically, as shown in FIG. 3, each chip pad 3 has an interlayer film 12 that is an insulation film and an aluminum film 13 that is a conductive film. Each chip pad 3 has the aluminum film 13 formed on the interlayer film 12. The aluminum film 13 is provided so as to cover the interlayer film 12. A top surface (in FIG. 3, an upper-side surface) 13a of the aluminum film 13 protrudes from a surface 11s of the passivation film 11 by a height d. Thus, the protruding portion of the chip pad 3 is part of the aluminum film 13.

FIG. 4 is a sectional view of one chip pad 3A having a different configuration from FIG. 3.

The chip pads 3A are formed so as to protrude through the openings 11a of the passivation film 11 of the semiconductor chip 1. More specifically, as shown in FIG. 4, each chip pad 3A has an aluminum film 14 that is a conductive film and an additional aluminum film 15 that is a conductive film. The additional aluminum film 15 is stacked on the aluminum film 14. When the aluminum film 14 is a first conductive film, the additional aluminum film 15 is a second conductive film that is formed so as to cover the aluminum film 14 by a rewiring process. A top surface (in FIG. 4, an upper-side surface) 15a of the additional aluminum film 15 protrudes from the surface 11s of the passivation film 11 by the height d. Thus, the protruding portion of the chip pad 3A is part of the additional aluminum film 15.

### (Manufacturing Method of Chip Pads)

A manufacturing method of the chip pads 3 will be described.

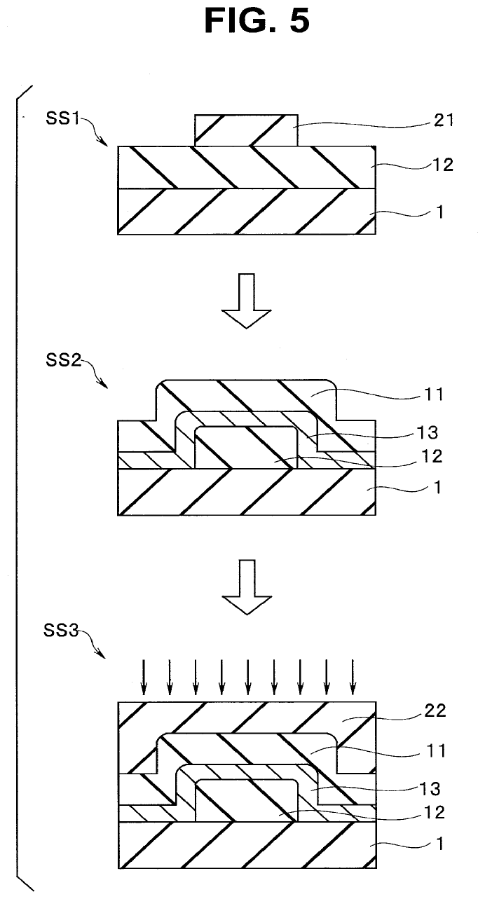

FIG. 5 is a view for describing the manufacturing method of the chip pads 3. FIG. 5 shows a section of one chip pad 3.

As shown in SS1 of FIG. 5, the interlayer film 12 that is an insulation film is formed on the surface of the semiconductor chip 1. Further, a photoresist 21 for RIE (reactive ion etching) is patterned on the interlayer film 12 according to a shape of the chip pad 3.

From the state of SS1, the interlayer film 12 is patterned according to the shape of the chip pad 3 by reactive ion etching (RIE), etc.

As shown in SS2, after the photoresist 21 is removed, the aluminum film 13 and the passivation film 11 are stacked on the surface of the semiconductor chip 1 by sputtering, application, etc.

After that, as shown in SS3, a protective film 22 is stacked by sputtering, etc. After that, entire surfaces of the protective film 22 and the passivation film 11 are etched back by reactive ion etching (RIE), CMP (chemical mechanical polishing), etc. As a result, the chip pad 3 as shown in FIG. 3 is formed.

A manufacturing method of the chip pads 3A will be described.

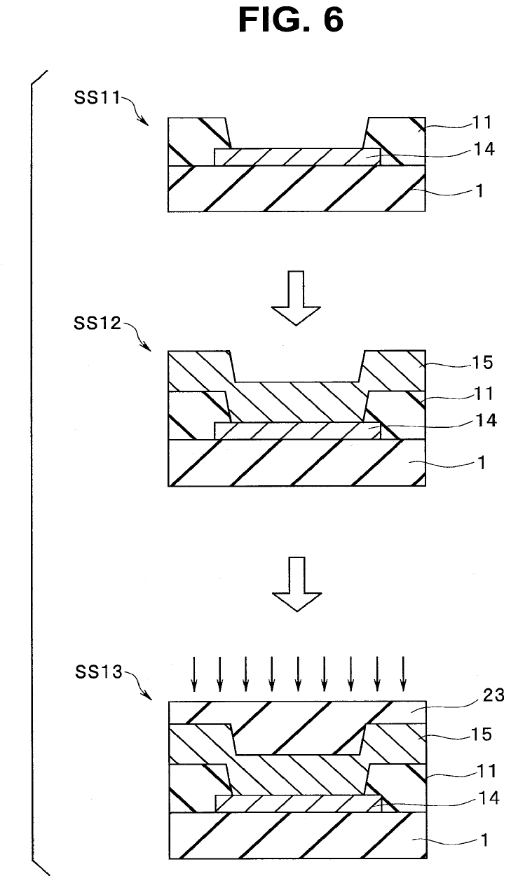

FIG. 6 is a view for describing the manufacturing method of the chip pads 3A. FIG. 6 shows a section of one chip pad 3A. After the aluminum film 14 for the chip pad is formed on the surface of the semiconductor chip 1, the passivation film 11 is applied. The passivation film 11 is patterned, and as shown in SS11, the aluminum film 14 is exposed at a bottom part of a recess formed in the passivation film 11 of the semiconductor chip 1.

In other words, the passivation film 11 is formed so as to rise above a periphery of the aluminum film 14 at the bottom part of the recess as shown in FIG. 6.

Next, as shown in SS12, the additional aluminum film 15 is stacked by sputtering, application, etc.

Then, as shown in SS13, a protective film 23 is stacked by sputtering, application, etc.

After that, entire surfaces of the protective film 23 and the additional aluminum film 15 are etched back by reactive ion etching (RIE), chemical mechanical polishing (CMP), etc. As a result, the chip pad 3A as shown in FIG. 4 is formed.

(Method of Bumplessly Installing Semiconductor Chip onto Substrate)

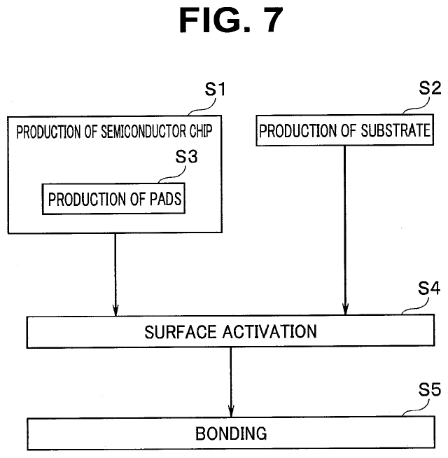

FIG. 7 is a view for describing a method of bumplessly installing the semiconductor chip 1 onto the substrate 2.

Production of the semiconductor chip 1 (S1) and production of the substrate 2 (S2) are separately performed. The production of the semiconductor chip 1 (S1) includes production of the plurality of chip pads 3 (or 3A) (S3). The production of the plurality of chip pads 3 (or 3A) (S3) is as shown in FIG. 5 (or FIG. 6).

Specifically, the semiconductor chip 1 having the passivation film 11 on one side of the semiconductor chip 1 is produced, and the plurality of chip pads 3 that are formed so as to protrude from the surface of the passivation film 11 are produced. The substrate 2 having the plurality of contact pads 4 is produced separately from the semiconductor chip 1.

After the production of the semiconductor chip 1 (S1) and the production of the substrate 2 (S2), a surface activation process (S4) is performed. The surface activation process (S4) is conducted on a surface of each of the plurality of chip pads 3 (or 3A) of the semiconductor chip 1 and the plurality of contact pads 4 of the substrate 2 under vacuum. An oxide film is formed on or various adsorbates adhere to the surfaces of the plurality of chip pads 3 (or 3A) and the plurality of contact pads 4. The oxide film, etc. are removed by the surface activation process (S4).

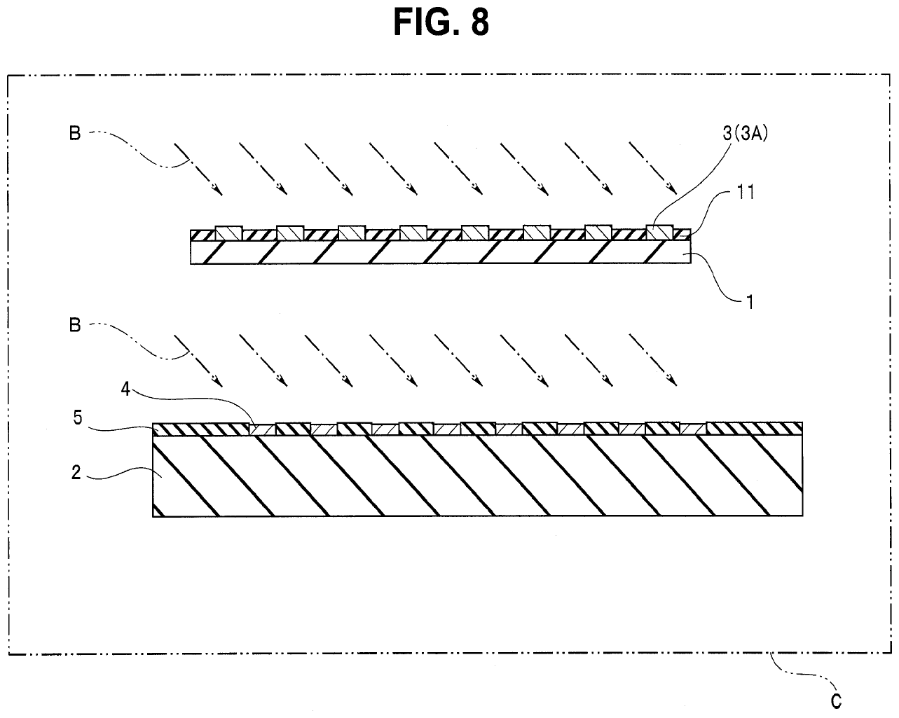

FIG. 8 is a view for describing the surface activation process for the semiconductor chip 1 and the substrate 2. As shown in FIG. 8, in the surface activation process (S4), the surfaces of the plurality of chip pads 3 (or 3A) and the plurality of contact pads 4 are irradiated with a beam B (indicated by dashed-dotted lines) that is an ion beam or a neutron beam inside a space C under high vacuum, so that the oxide film, etc. on the surfaces of joining materials (the plurality of chip pads 3 (or 3A) and the plurality of contact pads 4) are removed.

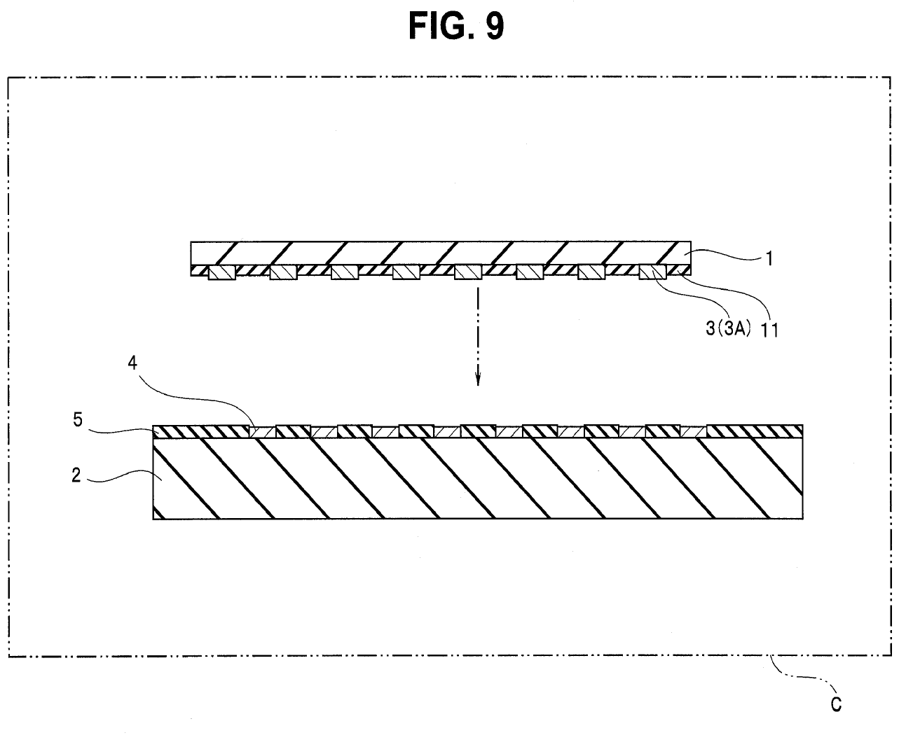

After the surface activation process (S4), a bonding process (S5) is performed. FIG. 9 is a view for describing bonding of the semiconductor chip 1 and the substrate 2. In the bonding process (S5), the plurality of chip pads 3 (or 3A) and the plurality of contact pads 4 are respectively brought into contact and joined together inside the space C under high vacuum and at room temperature.

More specifically, in the bonding process (S5), the plurality of chip pads 3 (or 3A) and the plurality of contact pads 4 are respectively aligned and then brought into contact with each other. As the plurality of chip pads 3 (or 3A) and the plurality of contact pads 4 are brought into contact with each other under high vacuum and at room temperature, the plurality of chip pads 3 (or 3A) and the plurality of contact pads 4 are instantly joined together. Since the surfaces of the plurality of chip pads 3 (or 3A) and the surfaces of the plurality of contact pads 4 have been subjected to the surface activation process, the plurality of chip pads 3 (or 3A) and the plurality of contact pads 4 are firmly joined together. Here, each chip pad 3 (or 3A) and each contact pad 4 are in contact with each other in a state where the oxide film or the adsorbate has been removed from a contact region between the chip pad 3 (or 3A) and the contact pad 4.

A conventional method of mounting the semiconductor chip 1 onto the substrate 2 using ball bumps involves a thermal process as an intermediate step, and thus leads to misalignment between the semiconductor chip 1 and the substrate 2 due to thermal stress, whereas joining of pads by the surface activation process does not involve a thermal process and therefore does not raise a problem of such misalignment.

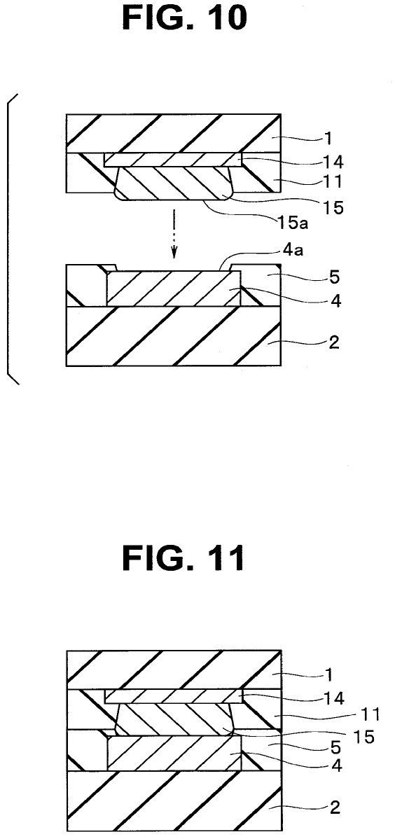

FIG. 10 and FIG. 11 are views for describing joining of the chip pads 3A and the contact pads 4. FIG. 11 shows a state where the top surface 15a of the additional aluminum film 15 is in contact with the surface 4a of the contact pad 4. The following description relating to FIG. 10 and FIG. 11 is applicable to joining of the chip pads 3 and the contact pads 4 as well.

As shown in FIG. 10, the semiconductor chip 1 and the substrate 2 are aligned and bonded together such that the top surface 15a of the additional aluminum film 15 of the chip pad 3A comes into contact with the surface 4a of the contact pad 4.

As shown in FIG. 10, in some cases, the surface 4a of the contact pad 4 is located on a bottom surface of a recess formed in a surface of the solder resist 5. In such a case, too, as shown in FIG. 11, the top surface 15a of the additional aluminum film 15 enters the recess of the solder resist 5 so as to fit in. This is because the top surface 15a of the additional aluminum film 15 protrudes from the surface of the passivation film 11.

Specifically, the substrate 2 has the solder resist 5 on the side onto which the semiconductor chip 1 is installed. Each contact pad 4 is formed in the recess formed in the solder resist 5, and the protruding portion of each chip pad 3 (or 3A) fits into the recess.

Since the surfaces 4a of the contact pads 4 and the surfaces of the chip pads 3A (the top surfaces 15a of the additional aluminum films 15) have been subjected to the surface activation process, these surfaces are instantly firmly joined together on contact with each other.

As has been described above, according to the above-described embodiment, the semiconductor device and the semiconductor device manufacturing method that allow the pads of the semiconductor chip and the pads of the substrate to be reliably joined together can be provided.

A plurality of chip pads of an ordinary semiconductor chip are located at lower positions than a surface of a passivation film (that is, positions where there is no passivation film). Therefore, when the activation process is merely performed, it is difficult to join the plurality of contact pads 4 of the substrate 2 and the chip pads 3 (or 3A) of the semiconductor chip 1 together by bringing these pads into contact with each other.

By contrast, according to the above-described embodiment, the chip pads 3 (or 3A) of the semiconductor chip 1 are formed so as to protrude from the surface of the passivation film 11, so that the pads having been subjected to the surface activation process are reliably firmly joined together.

Note that while aluminum is used as the material of each pad in the above-described embodiment, other conductive materials, such as copper, may be used.

### (Example of Unification)

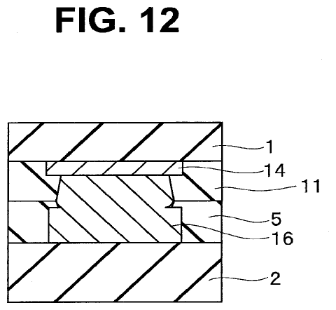

FIG. 12 is a view for describing unifying the pads of the semiconductor chip and the pads of the mounting substrate by joining these pads together.

In the example of FIG. 11, there are cases where the additional aluminum film 15 formed on the semiconductor chip 1 and the contact pads 4 formed on the substrate 2 are not metals of the same type. If the chip pads formed on the semiconductor chip 1 and the contact pads formed on the substrate 2 are metals of the same type, these metals are unified into a metal part 16 at a time of bumpless joining as shown in FIG. 12.

### Second Embodiment

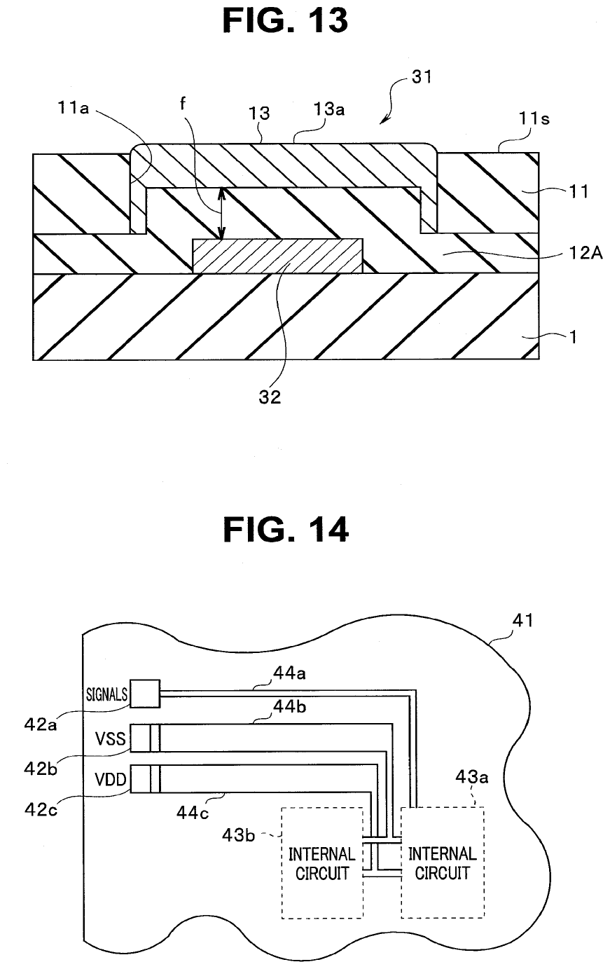

FIG. 13 is a sectional view of a chip pad 31 according to a second embodiment. Constituent elements in FIG. 13 that are the same as in FIG. 3 will be denoted by the same reference signs and the description will be omitted.

Like the chip pads 3 in the first embodiment, the chip pads 31 are formed so as to protrude through the openings 11a in the passivation film 11 of the semiconductor chip 1. As shown in FIG. 13, each chip pad 31 has an interlayer film 12A that is an insulation film and the aluminum film 13 that is a conductive film. A wiring layer 32 is formed on the surface of the semiconductor chip 1, and the interlayer film 12A is formed between the semiconductor chip 1 and the wiring layer 32 on one side and the passivation film 11 and the aluminum film 13 on the other side. The aluminum film 13 is formed above the wiring layer 32. The top surface (in FIG. 13, an upper-side surface) 13a of the aluminum film 13 protrudes from the surface 11s of the passivation film 11 as in the first embodiment. Thus, the protruding portion of the chip pad 31 is part of the aluminum film 13.

The semiconductor chip 1 having such chip pads 31 is also bumplessly installed onto the substrate 2 (see FIG. 1). Specifically, a surface of each of the plurality of chip pads 31 of the semiconductor chip 1 and the plurality of contact pads 4 of the substrate 2 is subjected to the surface activation process under vacuum. After the surface activation process, a bonding process is performed. In the bonding process, the plurality of chip pads 31 and the plurality of contact pads 4 are respectively brought into contact and joined together by exerting an appropriate pressure under high vacuum and at room temperature.

In the second embodiment, as described above, the wiring layer 32 is provided in a layer under the chip pads 31 on a side of a circuit mounting side of the semiconductor chip 1. As a distance between an upper surface of the wiring layer 32 and a bottom surface of the aluminum film 13, that is, a thickness of the interlayer film 12A between the wiring layer 32 and the aluminum film 13, f is set.

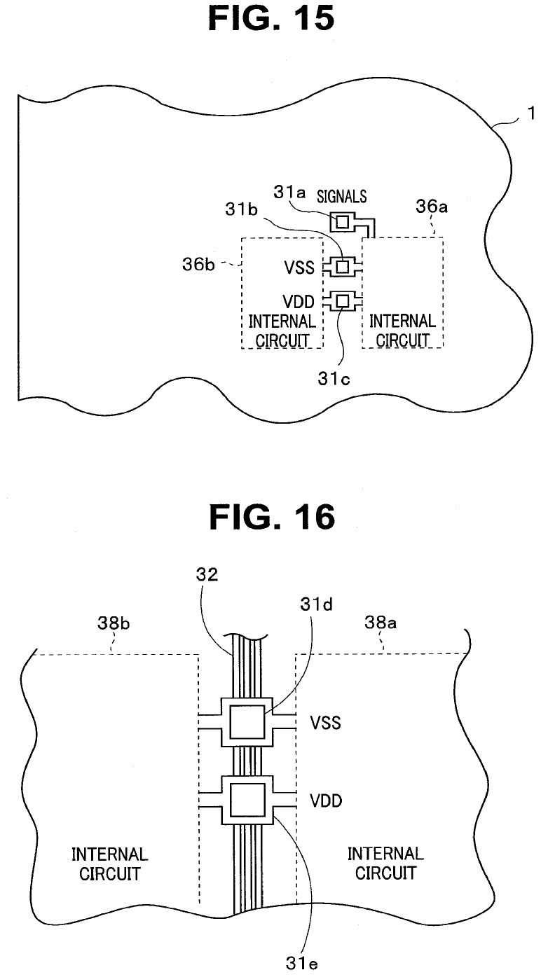

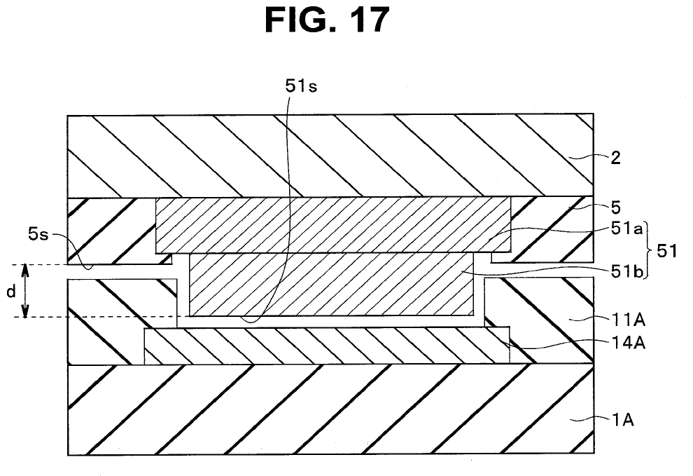

FIG. 14 to FIG. 16 are explanatory diagrams for describing states where the chip pads 31 are disposed on a layer above the wiring layer 32. FIG. 14 is an explanatory diagram showing a comparative example of arrangement of the chip pads on the semiconductor chip. FIG. 15 is an explanatory diagram showing an example of arrangement of the chip pads 31 of the semiconductor chip 1. FIG. 16 is an explanatory diagram for describing the chip pads 31 disposed on the layer above the wiring layer 32.

In the comparative example of FIG. 14, chip pads 42a, 42b, 42c (which will be hereinafter referred to as chip pads 42 when there is no need to make a distinction) are disposed at a marginal portion of a semiconductor chip 41. For example, the chip pads 42a, 42b, 42c are for signals, a power source VSS, and a power source VDD, respectively. The chip pads 42a, 42b, 42c are connected to internal circuits 43a, 43b configured in the semiconductor chip 41 by wiring layers 44a, 44b, 44c, respectively. The chip pads 42 in the comparative example are connected to pads on a substrate, which is not shown, by bonding wires. In a wire bonding step, to allow for damage to the chip pads 42, for example, the chip pads 42 are formed in a comparatively large size, such as 45 μm on a side, and a comparatively large space needs to be left between the chip pads 42.

By contrast, in the example of FIG. 15, the semiconductor chip 1 is bumplessly installed and therefore a pressure on the chip pads 31 during clamping is relatively low. Accordingly, the size of the chip pads 31 can be made comparatively small. For example, the size of the chip pads 31 can be set to about 3 to 10 μm on a side. As a result, as shown in FIG. 15, the plurality of chip pads 31 (31a, 31b, 31c) can be disposed in gaps between internal circuits 36a, 36b configured in the semiconductor chip 1.

According to this configuration, wires between each chip pad 31 and the internal circuits 36a, 36b can be shortened and wiring resistance and a wiring capacity can be reduced to contribute to achieving higher speed. However, as shown in FIG. 16, in some cases, the wiring layer 32 is disposed between internal circuits 38a, 38b and the chip pads 31 are disposed on the wiring layer 32. In FIG. 16, chip pads 31 (31d, 31e) disposed on the wiring layer 32 are shown. In this case, even when the bumpless installation method is adopted, it is conceivable that more or less stress may be placed on the wiring layer 32 in a layer under the chip pads 31 during joining of the semiconductor chip 1 and the substrate 2.

In the second embodiment, therefore, the interlayer film 12A with the predetermined thickness f is formed to protect the wiring layer 32. Note that when the bumpless installation method is adopted, a pressure during bumpless installation is dispersed among all the chip pads 31 on the semiconductor chip 1, so that a pressure applied to one chip pad 31 is considered to be comparatively low. With these factors taken into account, for example, a thickness from a thickness equivalent to a thickness of a layer formed as an ordinary interlayer film to a thickness of about 2.5 times a thickness of the wiring layer 32 is set as f. For example, a thickness of 0.5 to 2.8 μm may be adopted as f.

As has been described, in the second embodiment, it is possible to dispose each chip pad 31 above the wiring layer 32 by setting the thickness of the interlayer film 12A between the aluminum film 13 constituting the chip pad 31 and the wiring layer 32 to the appropriate thickness f. The appropriate thickness can be set according to a size and a number of the chip pads, a pressure during joining in bumpless installation, etc.

### Third Embodiment

FIG. 17 is a sectional view showing a third embodiment. FIG. 17 shows sections of a semiconductor chip and a substrate. In the first embodiment, as shown in FIG. 10 and FIG. 11, the chip pad 3 (or 3A) of the semiconductor chip 1 is protruded and the protruding portion of the chip pad 3 (or 3A) is fitted into a recess formed in the solder resist 5 of the substrate 2 to couple together the chip pad 3 (or 3A) and the contact pad 4 formed in the recess of the solder resist 5. On the other hand, in the third embodiment, as shown in FIG. 17, a contact pad 51 of the substrate 2 is protruded and the protruding portion of the contact pad 51 is fitted into a recess formed in a passivation film 11A of a semiconductor chip 1A to couple together a chip pad 14A formed in a recess of the passivation film 11A and the contact pad 51. In the third embodiment, too, the semiconductor chip 1A is bumplessly installed onto the substrate 2.

Like the semiconductor chip 1, the semiconductor chip 1A is a bare chip that has been cut out and singulated from a semiconductor wafer, and is mounted onto the substrate 2 by the flip-chip method. The semiconductor chip 1A is a plate-shaped chip and, for electrical connection to the substrate 2, has a plurality of chip pads 14A formed by an aluminum film that is a conductive film.

Each chip pad 14A is formed inside the recess formed in the passivation film 11A of the semiconductor chip 1A. Specifically, a top surface (in FIG. 17, an upper-side surface) of the chip pad 14A is recessed from a surface of the passivation film 11A by a predetermined distance.

### (Configuration of Contact Pads)

On the other hand, a plurality of copper wiring films 51a are provided on the surface of the substrate 2 onto which the semiconductor chip 1A is mounted. Specifically, the substrate 2 has the plurality of copper wiring films 51a on the side facing a side of the semiconductor chip 1A that has the plurality of chip pads 14A. The solder resist 5 is applied to the surface of the substrate 2. The solder resist 5 has open portions in formation regions of the copper wiring films 51a on the surface of the substrate 2. Thus, the solder resist 5 is not applied to a large part of a surface of each of the plurality of copper wiring films 51a.

In the third embodiment, as shown in FIG. 17, an additional metal film 51b that is a conductive film is formed on each copper wiring film 51a that is a conductive film. Thus, each contact pad 51 has the copper wiring film 51a and the additional metal film 51b. A top surface (in FIG. 17, a lower-side surface) 51s of the additional metal film 51b protrudes from a surface 5s of the solder resist 5 by a height d. Thus, the protruding portion of the contact pad 51 is part of the additional metal film 51b.

The semiconductor chip 1A having the chip pads 14A is bumplessly installed onto the substrate 2 having such contact pads 51. The technique of bumpless installation is the same as in the first embodiment. Specifically, a surface of each of the plurality of chip pads 14A of the semiconductor chip 1A and the plurality of contact pads 51 of the substrate 2 is subjected to the surface activation process under vacuum. After the surface activation process, the bonding process is performed.

More specifically, in the bonding process, the plurality of chip pads 14A and the plurality of contact pads 51 are respectively aligned and then brought into contact with each other. Note that FIG. 17 shows a state where the alignment before bringing into contact has been performed. As the plurality of chip pads 14A and the plurality of contact pads 51 are brought into contact with each other under high vacuum and at room temperature, the plurality of chip pads 14A and the plurality of contact pads 51 are instantly joined together.

### (Manufacturing Method of Contact Pads)

Next, a manufacturing method of the contact pads 51 will be described.

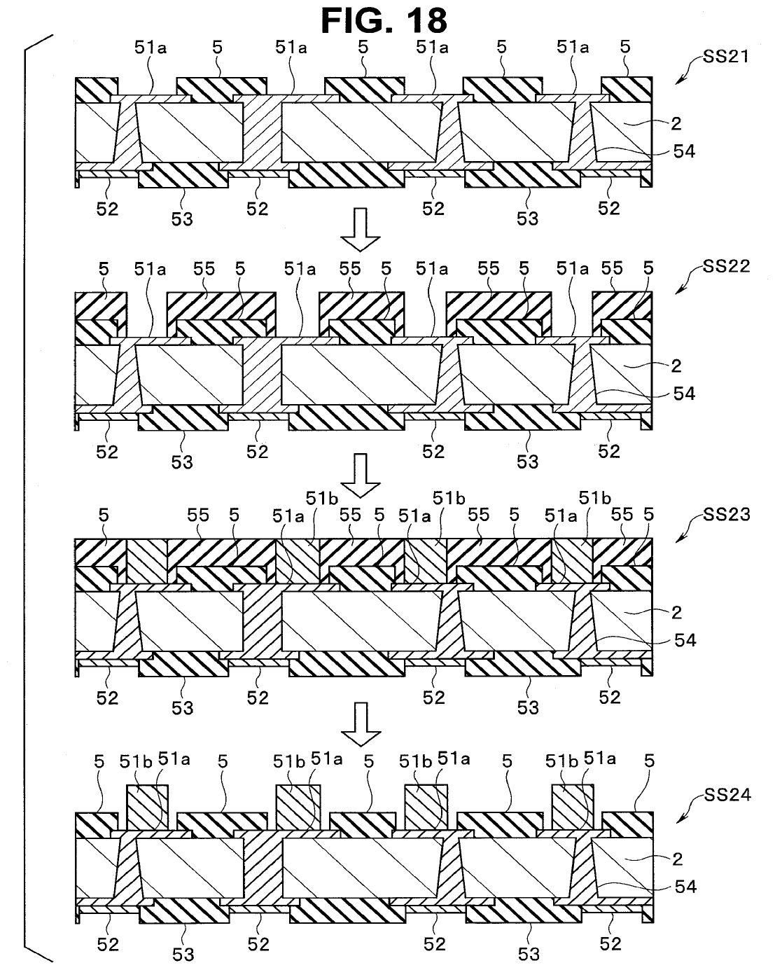

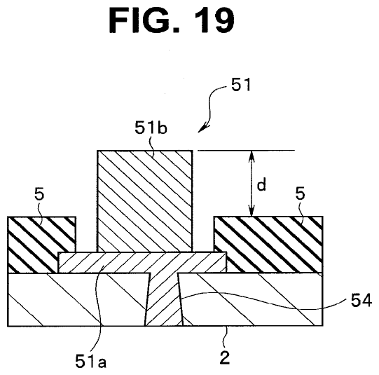

FIG. 18 and FIG. 19 are views for describing the manufacturing method of the contact pads 51. The example of FIG. 18 is application to an ordinary two-layer package substrate.

As shown in SS21 of FIG. 18, the copper wiring films 51a are formed on the surface of the substrate 2. The copper wiring films 51a are each connected to a copper wiring pattern 52 formed on a back surface of the substrate 2 through a through-hole 54. Further, the solder resist 5 is formed on the surface of the substrate 2, and a solder resist 53 is formed on the back surface. A large part of the surface of each copper wiring film 51a is not covered by the solder resist 5.

As shown in SS22, a photoresist 55 for reactive ion etching (RIE) is patterned on a front surface side of the substrate 2 according to shapes of the copper wiring films 51a.

Note that in this case, each opening of the photoresist 55 is set to be somewhat smaller than an opening of the solder resist 5 to allow for alignment error.

As shown in SS23, a copper or gold pillar is grown in each open part of the photoresist 55 by non-electrolytic plating or electrolytic plating. Note that when growing gold, nickel as a base film is grown to 500 nm by plating on a surface of each copper wiring film 51a. In this way, the contact pads 51 each including the copper wiring film 51a and the additional metal film 51b are formed.

Finally, as shown in SS24, the photoresist 55 is detached to complete the contact pads.

As shown in FIG. 19, the height d from an upper surface of the solder resist 5 to an upper surface of the additional metal film 51b is set according to the pad structure of the semiconductor chip 1A.

As has been described, in the third embodiment, effects similar to those of the first embodiment can be achieved by protruding the contact pads of the substrate.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

1. A semiconductor device comprising:
a semiconductor chip including a passivation film on a first side; and
a mounting substrate including a second side facing the first side of the semiconductor chip, wherein:
the semiconductor chip includes a wiring layer formed on the first side, a first pad formed on the first side so as to protrude from a surface of the passivation film, and an interlayer film formed between the first side and the wiring layer on one side and the passivation film and the first pad on another side;
the mounting substrate includes a second pad on the second side;
the first pad and the second pad are in contact with each other in a state where an oxide film or an adsorbate is removed from a contact region between the first pad and the second pad;
a thickness of the interlayer film between the wiring layer and the first pad is 0.5 to 2.8 μm;
the semiconductor chip includes a plurality of internal circuits provided adjacent to one another; and
the first pad is disposed between formation regions of the internal circuits.

2. The semiconductor device according to claim 1, wherein a pad size of the first pad is 3 to 10 μm.

3. The semiconductor device according to claim 1, wherein the wiring layer is provided between formation regions of the internal circuits, and the first pad is disposed on a layer above the wiring layer.

4. The semiconductor device according to claim 1, wherein the first pad and the wiring layer are not connected to each other directly under the first pad.

5. A semiconductor device comprising:
a semiconductor chip including a passivation film on a first side; and
a mounting substrate including a second side facing the first side of the semiconductor chip, wherein:
the semiconductor chip includes a first pad formed on the first side so as to protrude from a surface of the passivation film;
the mounting substrate includes a second pad on the second side; and
the first pad and the second pad are in contact with each other in a state where an oxide film or an adsorbate is removed from a contact region between the first pad and the second pad.

6. The semiconductor device according to claim 5, wherein:
the mounting substrate includes a solder resist provided on the second side;
the second pad is formed in a recess formed in the solder resist; and
the protruding portion of the first pad fits into the recess.

7. The semiconductor device according to claim 5, wherein:
the first pad includes a conductive film formed on an insulation film; and
the protruding portion of the first pad is part of the conductive film.

8. The semiconductor device according to claim 5, wherein:
the first pad includes a second conductive film stacked on a first conductive film; and
the protruding portion of the first pad is part of the second conductive film.

9. The semiconductor device according to claim 5, wherein the semiconductor chip is a non-volatile memory chip, or a controller chip that controls the non-volatile memory.

10. The semiconductor device according to claim 5, wherein the first pad is formed using aluminum as a conductive material.

11. A semiconductor device comprising:
a mounting substrate including a solder resist on a first side; and
a semiconductor chip including a second side facing the first side of the mounting substrate, wherein:
the mounting substrate includes a first pad formed on the first side so as to protrude from a surface of the solder resist;
the semiconductor chip includes a second pad on the second side; and
the first pad and the second pad are in contact with each other in a state where an oxide film or an adsorbate is removed from a contact region between the first pad and the second pad.

12. The semiconductor device according to claim 11, wherein:
the first pad includes a copper wiring film and an additional metal film stacked on the copper wiring film; and
the protruding portion of the first pad is part of the additional metal film.

13. The semiconductor device according to claim 11, wherein the semiconductor chip is a non-volatile memory chip, or a controller chip that controls the non-volatile memory.

14. The semiconductor device according to claim 11, wherein the second pad is formed using aluminum as a conductive material.
